(19) United States
(12) Patent Application Publication
(10) Pub. No.: US 2023/0360988 A1
(43) Pub. Date: Nov. 9, 2023

(54) POTTED ELECTRONIC CIRCUIT

(71) Applicant: SEMIKRON ELEKTRONIK GMBH &CO.KG, Nuremberg (DE)

(72) Inventors: Eike HAHN, Erlanger (DE); Christian Gõbl, Nuremberg (DE)

(73) Assignee: SEMIKRON ELEKTRONIK GMBH &CO.KG, Nuremberg (DE)

(21) Appl. No.: 18/140,388

(22) Filed: Apr. 27, 2023

(30) Foreign Application Priority Data
May 6, 2022 (DE) 10-2022-111-320.5

(51) Int. Cl. H01L 23/31; H01L 23/495; H01L 23/29

(52) U.S. Cl. CPC H01L 23/3121; H01L 23/49586; H01L 23/295; H01L 2224/48175; H01L 24/48

(57) ABSTRACT

An electronic circuit includes a circuit carrier (1), a metal layer (9) and an electrically insulating base layer (2) on the metal layer (9). Conductor tracks (3) are on the base layer (2) and electronic components (4) are arranged on the conductor tracks (3). The conductor tracks (3) and the electronic components (4) are covered using a potting compound (10). A separating layer (11) is arranged between the base layer (2) and the potting compound (10) at least in the areas between the conductor tracks (3). The separating layer (11) consists of an electrically insulating material, which is different from both the material of the base layer (2) and the material of the potting compound (10).

### CROSS REFERENCE TO RELATED APPLICATIONS

This application relates to and claims priority to DE 10 2022 111 320.5 filed May 6, 2022, the entire contents of which are incorporated herein fully by reference.

### FIGURE SELECTED FOR PUBLICATION

FIG. 2.

### BACKGROUND OF THE INVENTION

### Field of the Invention

The present invention is directed to an electronic circuit,
wherein the electronic circuit includes a circuit carrier,
wherein the circuit carrier includes a metal layer and an electrically insulating base layer on the metal layer,
wherein conductor tracks are arranged on the base layer and electronic components are arranged on the conductor tracks,
wherein the conductor tracks and the electronic components are covered using a potting compound.

### Description of the Related Art

An electronic circuit has to be operationally reliable. A safeguard against inadvertent touching of the conductor tracks and the electronic components is often also required for this purpose. To ensure such touch safety, the conductor tracks and the electronic components are often covered using a potting compound. In many cases, the potting compound is permanently elastic. In other cases, the potting compound is a hard potting compound, for example a potting compound consisting of an epoxy resin.

An electronic circuit is furthermore often subjected to significant temperature variations in operation. Such temperature variations can result in significant mechanical loads of the electronic circuit due to different coefficients of expansion of materials used. In some cases, such mechanical loads can result in fractures. It often occurs in practice that electrical contacts are interrupted due to such fractures or undesired—sometimes even hazardous, in the extreme case even life-threatening—electrical contacts are created or creepage distances, which are required for safety reasons, are no longer maintained. Cracks can also arise in the base layer, into which moisture can penetrate. This can also have the result that properties of the electronic circuit required for safety reasons are no longer maintained.

Attempts have been made in practice to counter this problem in that the conductor tracks and the electronic components are covered using a potting compound. In some cases, however, cracks arise in the base layer in spite of such a potting compound and sometimes even because of such a potting compound. It may also occur that the base layer detaches from the metal layer.

An electronic circuit is known from DE 10 2013 013 842 A1, which includes a circuit carrier. The circuit carrier includes a metal layer and an electrically insulating base layer on the metal layer. Conductor tracks are arranged on the base layer, and electronic components are arranged on the conductor tracks. Possible cracks in the base layer are closed by pressing a free-flowing compound into the cracks.

### ASPECTS AND OBJECTS OF THE INVENTION

The object of the present invention is to create possibilities by means of which cracks occurring in the base layer, in particular due to mechanical stresses can be avoided.

The object is achieved by an electronic circuit having the features of one or more of the proposed claims.

According to the invention, an electronic circuit of the type mentioned at the outset is designed in that a separating layer, which consists of an electrically insulating material that is different from both the material of the base layer and the material of the potting compound, is arranged at least in the areas between the conductor tracks between the base layer and the potting compound.

The use of a material which is different from both the material of the base layer and the material of the potting compound has the result in particular that direct contact no longer exists between the base layer and the potting compound. It is thus possible to avoid in particular that forces are transmitted directly to the base layer via the potting compound, which can result therein in the mentioned cracks.

In a minimal embodiment, the separating layer is applied to the base layer in such a way that it is arranged exclusively in the area between the conductor tracks, but not also on the conductor tracks and the electronic components. Alternatively, it is possible that the separating layer is applied flatly to the base layer in such a way that it is arranged not only in the area between the conductor tracks, but rather also on the conductor tracks, but not on the electronic components. In a further alternative, it is possible that the separating layer is applied flatly to the base layer in such a way that it is arranged not only in the area between the conductor tracks, but rather also on the conductor tracks and the electronic components. A person skilled in the art will choose which of these designs is used.

The separating layer can consist of a permanently elastic material. In particular—but not only—in this case, the separating layer can have a hardness between 5 and 70 Shore A and/or a dielectric strength of at least 1 kV/mm. The dielectric strength is preferably significantly greater, in particular at least 5 kV/mm. The numeric specifications relate to the final state of the electronic circuit, thus when the electronic circuit can be continuously operated, not to possible intermediate states in the context of the production of the electronic circuit.

It has proven to be advantageous in experiments if the separating layer consists of an epoxy lacquer, of an acrylate, or of a polyurethane, in the last-mentioned case in particular of a polyurethane resin.

The potting compound can be formed in the specific case as a soft, in particular permanently elastic potting compound. However, the potting compound is generally formed as a hard potting compound. The potting compound can consist, for example, of an epoxy resin.

To increase the mechanical strength and/or the dielectric strength, it is advantageous if the potting compound contains grains made of silicon dioxide and/or antimony trioxide and/or boron nitride. Analogously, it is often advantageous if the base layer contains grains made of aluminum oxide.

The separating layer preferably has a height which is less than the height of the conductor tracks. The electrical properties are thus still determined by the potting compound—in particular between the conductor tracks. This applies to a greater extent the less the height of the separating layer is. The height of the separating layer is therefore preferably at most 80% of the height of the conductor tracks, in particular at even smaller values, for example at most 50%, at most 30%, and very preferably at most 10%.

The separating layer preferably consists of a material wetting the base layer and the conductor tracks. It is thus ensured in particular that the separating layer is also applied in the particularly critical boundary area between the base layer and a conductor track. The wetting property applies at least for the state upon application of the still free-flowing—at this point in time—separating layer.

The distance of the conductor tracks from one another is preferably at least as great as the height of the conductor tracks. This embodiment facilitates the application of the separating layer to the area between the conductor tracks.

In specific cases, it can be sufficient if the separating layer is only arranged in the areas between the conductor tracks. However, the separating layer is usually also arranged between the base layer and the potting compound in the areas between the conductor tracks and the edge of the base layer.

The distance of the conductor tracks from the edge of the base layer is preferably at least as great as the height of the conductor tracks. It is thereby achieved that the separating layer is also able to be reliably applied in the areas between the conductor tracks and the edge of the base layer.

In principle, the base layer can consist of any electrically insulating material. However, it preferably consists of an epoxy resin.

The electronic circuit is preferably operable in a temperature range which extends at least from −40° C. to +125° C. The mentioned values characterize a minimum requirement. Of course, operability even at temperatures below −40° C. and/or above 125° C. is even better.

The above and other aspects, features, objects, and advantages of the present invention will become apparent from the following description read in conjunction with the accompanying drawings for exemplary but nonlimiting embodiments, in which like reference numerals designate the same elements.

### BRIEF DESCRIPTION OF THE DRAWINGS

FIG. 1 is a top view of an electronic circuit.

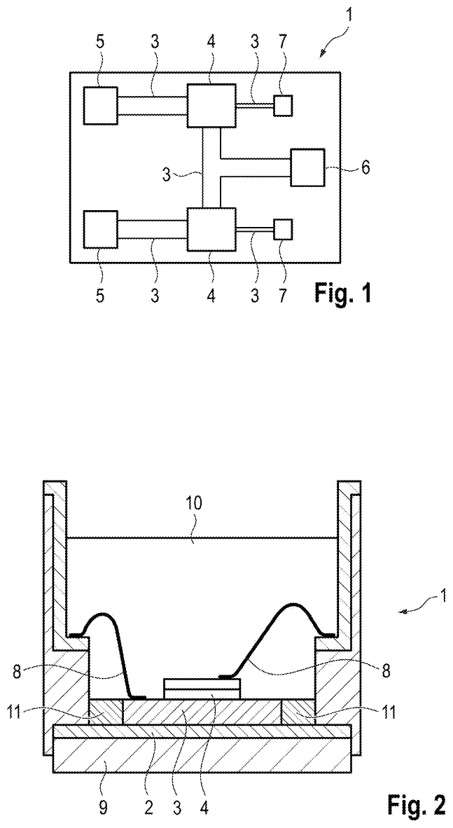

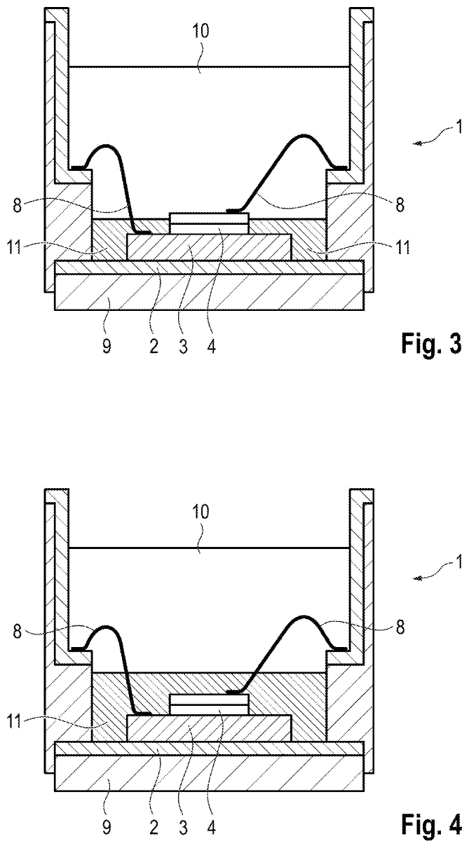

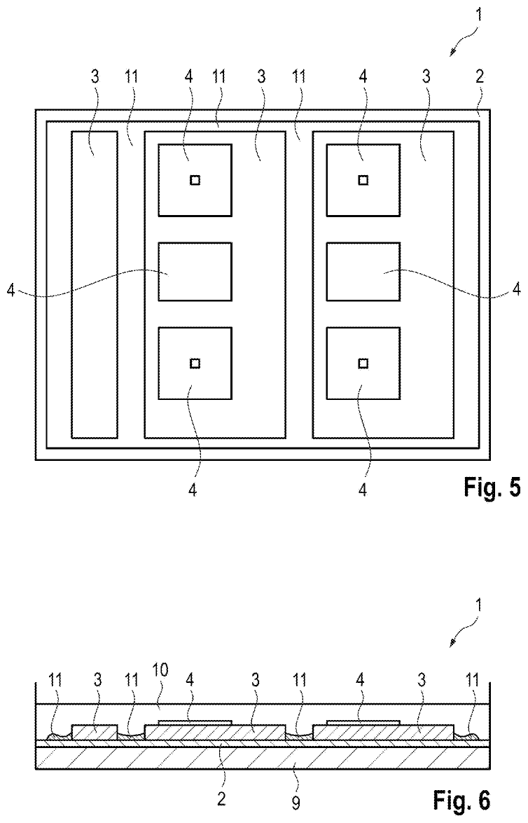

FIGS. 2 to 4 show sections through possible designs of the electronic circuit of FIG. 1.

FIG. 5 show a top view of a further electronic circuit (without potting compound).

FIG. 6 shows a section through the electronic circuit of FIG. 5 (with potting compound).

### DETAILED DESCRIPTION OF THE PREFERRED EMBODIMENTS

Reference will now be made in detail to embodiments of the invention. Wherever possible, same or similar reference numerals are used in the drawings and the description to refer to the same or like parts or steps. The drawings are in simplified form and are not to precise scale. The word ‘couple’ and similar terms do not necessarily denote direct and immediate connections, but also include connections through intermediate elements or devices. For purposes of convenience and clarity only, directional (up/down etc.) or motional (forward/back, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

According to FIGS. 1 to 4, an electronic circuit includes a circuit carrier 1. The circuit carrier 1 in turn includes a base layer 2. The base layer 2 consists of an electrically insulating material. In general, the base layer 2 consists of an epoxy resin. Conductor tracks 3 are arranged on the base layer 2. Electronic components 4 are in turn arranged on the conductor tracks 3. The electronic components 4 are each arranged on at least two of the conductor tracks 3. The electronic components 4 are interconnected via the conductor tracks 3.

Solely by way of example, a half-bridge of an inverter circuit is shown in FIG. 1. In the case of this design, the electronic circuit can include as electronic components 4, for example, two electronic switching elements, in particular transistors. The transistors are connected in series in this case. The two ends of the series circuit are connected via connecting surfaces 5 to a high potential and a low potential, and a node point of the series circuit between the two transistors is connected via a further connecting surface 6 to an AC potential. Control signals for switching the electronic switching elements can be supplied to the electronic switching elements via further connecting surfaces 7. The further connecting surfaces 7 can be arranged according to the illustration in FIG. 1 on the base layer 2 as such or according to the illustration in FIGS. 2 to 4 directly on the electronic switching elements. Connections continuing outward can be produced, for example, via bond wires 8 (see FIGS. 2 to 4).

However, the electronic circuit could also be designed differently at any time. The present invention is thus restricted neither to a half-bridge of an inverter circuit nor to an inverter circuit in general.

According to FIGS. 2 to 4, the conductor tracks 3 and the electronic components 4 (and also the connecting surfaces 5, 6) are exclusively arranged on one side of the base layer 2. Neither conductor tracks nor electronic components are located on the opposite side of the base layer 2, rather a metal layer 9. In other words, the base layer 2 is thus also arranged on the metal layer 9.

It is possible that the base layer 2 is relatively thick (up to approximately 2 mm) and the metal layer 9 is relatively thin (up to 0.5 mm). In this case, the base layer 2 can assume a mechanical support function, thus effect the mechanical stability of the circuit carrier 1. Alternatively, it is possible that the base layer 2 is relatively thin, for example less than 0.5 mm, in particular only somewhat more than 0.1 mm. In this case, the base layer 2 is not capable of effecting the mechanical support function of the circuit carrier 1. In this case, the mechanical support function has to be assumed by the metal layer 9. The thickness of the metal layer 9 is in this case often in the range between 1 mm and 3 mm, usually at approximately 2 mm. Examples of such circuit carriers 1 are an IMS (=insulated metal substrate) and an IMB (=insulated metal baseplate).

Alternatively, the circuit carrier 1 can be designed like a typical printed circuit board, in which the base layer 2 as such is mechanically stable per se, thus can also assume the mechanical support function for the conductor tracks 3 and the electronic components 4.

According to FIGS. 2 to 4, the conductor tracks 3 and the electronic components 4 are furthermore covered using a potting compound 10. A separating layer 1I is arranged at least in the areas between the conductor tracks 3, however, between the base layer 2 and the potting compound 10. Various embodiments are possible in this case according to FIGS. 2 to 4.

It is thus possible—see FIG. 2—that the separating layer 11 is applied to the base layer 2 in such a way that it is exclusively arranged in the area between the conductor tracks 3, but not also on the conductor tracks 3 and the electronic components 4. Alternatively, it is possible—see FIG. 3—that the separating layer 11 is applied flatly to the base layer 2 in such a way that it is arranged not only in the area between the conductor tracks 3, but rather also on the conductor tracks 3, but not on the electronic components 4. In another alternative, it is possible—see FIG. 4—that the separating layer 11 is applied flatly to the base layer 2 in such a way that it is arranged not only in the area between the conductor tracks 3, but also on the conductor tracks 3 and the electronic components 4. Independently of the specific implementation, however, the separating layer 11 consists of an electrically insulating material, which is different from both the material of the base layer 2 and the material of the potting compound 10.

The separating layer 11 is preferably arranged not only in the area between the conductor tracks 3 as such, but rather is arranged at least everywhere no conductor tracks are located. The separating layer 11 is therefore preferably also arranged between the base layer 2 and the potting compound 10 in the areas between the conductor tracks 3 and the edge of the base layer 2.

The separating layer 11 preferably consists of a permanently elastic material. In particular, it can have a hardness between 5 and 70 Shore A. Furthermore, the separating layer 11 is preferably to have a dielectric strength of at least 1 kV/mm. Greater values of, for example, at least 1 kV/mm or of at least 10 kV/mm are preferred. Furthermore, the separating layer 11 preferably consists of a material which wets the base layer 2 and the conductor tracks 3. For example, the separating layer 11 can consist of an epoxy lacquer, an acrylate, or a polyurethane. In the last-mentioned case, it can consist in particular of a polyurethane resin. Suitable polyurethane resins are sold, for example, by Lackwerke Peters GmbH & Co. KG, 47906 Kempen, under the name ELPEGUARD. In contrast, the potting compound 10 is generally designed as a hard potting compound in the scope of the present invention. It can consist of an epoxy resin, for example.

To improve the electric properties, the potting compound 10 can contain filler particles made of silicon dioxide (SiO₂) and/or antimony trioxide (Sb₂O₃) and/or boron nitride (BN). For the same reasons, the base layer 2 can contain filler particles made of aluminium oxide (Al₂O₃).

FIGS. 5 and 6 show a further electronic circuit. This circuit is designed with respect to the approach in the same manner as the electronic circuit of FIGS. 1 to 4. However, FIGS. 5 and 6 additionally show several further advantageous embodiments of the present invention.

It is apparent from FIGS. 5 and 6, for example, that the separating layer 11 is not only applied between the conductor tracks 3 on the base layer 2, but also in the area between the outer conductor tracks 3 and the edge of the base layer 2. Furthermore, it is apparent that the separating layer 11 has a height which is less than the height of the conductor tracks 3 and that the distance of the conductor tracks 3 both from one another and from the edge of the base layer 2 is at least as great as the height of the conductor tracks 3. It is furthermore apparent from FIGS. 5 and 6 that the separating layer 11 is introduced into all “trenches” (thus the areas between each two conductor tracks 3).

The electronic circuit is preferably to be able to be operated in a temperature range which extends from −40° C. (if possible, also even lower temperatures) to +125° C. (if possible also even higher temperatures). The material of which the separating layer 11 consists is therefore preferably to be selected in such a way that it is stable in this temperature range. Corresponding materials are known for the other components of the electronic circuit.

The present invention has many advantages. In particular, in the cases in which the base layer 2 consists of an epoxy resin and the potting compound 10 is a hard potting compound—in particular also consists of an epoxy resin—the service life of the electronic circuit is significantly improved even in the case of greater, repeated temperature variations.

The above description is used exclusively to explain the present invention. In contrast, the scope of protection of the present invention is to be defined exclusively by the appended claims.*

The preceding description is intended exclusively for the illustration of the present invention. Conversely, the scope of protection of the present invention is dictated exclusively by the attached claims.

### LIST OF REFERENCE SYMBOLS

1 circuit carrier
2 base layer
3 conductor tracks
4 electronic components
5 to 7 connecting surfaces
8 bond wires
9 metal layer
10 potting compound
11 separating layer

Also, the inventors intend that only those claims which use the specific and exact phrase “means for” are intended to be interpreted under 35 USC 112. The structure herein is noted and well supported in the entire disclosure. Moreover, no limitations from the specification are intended to be read into any claims, unless those limitations are expressly included in the claims.

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure cover modifications and variations of this disclosure provided they come within the scope of the appended claims and their equivalents.

What is claimed is:

1. An electronic circuit, comprising a circuit carrier (1), wherein:
said circuit carrier (1) further comprises:
a metal layer (9) and an electrically insulating base layer (2) on the metal layer (9);
a plurality of conductor tracks (3) are arranged on the base layer (2) and a plurality of electronic components (4) are arranged on the conductor tracks (3);
the plurality of conductor tracks (3) and the electronic components (4) are covered using a potting compound (10);
a separating layer (11) that consists of an electrically insulating material is different from both a base layer material of the base layer (2) and the potting compound (10); and
said separating layer (11) is arranged at least in the areas between the conductor tracks (3) and between the base layer (2) and the potting compound (10).

2. The electronic circuit, according to claim 1, wherein:
the separating layer (11) is applied on the base layer (2); and
at least one of:
a) exclusively at sides of respective conductor tracks (3), and not on the conductor tracks (3) and not on the plurality of electronic components (4);
b) at said sides of respective conductor tracks (3) and also on the respective conductor tracks (3) and not on the plurality of electronic components (4); and
c) to said sides of respective conductor tracks (3) and also on the respective conductor tracks (3) and also on the plurality of electronic components (4).

3. The electronic circuit, according to claim 2, wherein:
the separating layer (11) consists of a permanently elastic material.

4. The electronic circuit, according to claim 3, wherein:
the separating layer (11) has a hardness between 5 and 70 Shore A; and
the separating layer (11) has a dielectric strength of at least one of 1 kV/mm and 5 kV/mm.

5. The electronic circuit, according to claim 3, wherein:
the separating layer (11) consists of at least one of an epoxy lacquer, an acrylate, a polyurethane, and a polyurethane resin.

6. The electronic circuit, according to claim 3, wherein:
the potting compound (10) is a hard potting compound.

7. The electronic circuit, according to claim 6, wherein:
the potting compound (10) is an epoxy resin.

8. The electronic circuit, according to claim 6, wherein:
the potting compound (10) contains filler particles made of one of silicon dioxide, antimony trioxide, and boron nitride.

9. The electronic circuit, according to claim 3, wherein:
the base layer (2) contains filler particles made of aluminum oxide.

10. The electronic circuit, according to claim 3, wherein:
the separating layer (11) has a thickness which is less than a height of the respective conductor tracks (3).

11. The electronic circuit, according to claim 3, wherein:
the separating layer (11) consists of a material wetting the base layer (2) and the conductor tracks (3).

12. The electronic circuit, according to claim 3, wherein:
a spacing distance between respective conductor tracks (3) is at least as great as a height of the respective conductor tracks (3).

13. The electronic circuit, according to claim 2, wherein:
the separating layer (11) is arranged between the base layer (2) and the potting compound (10) between the conductor tracks (3) and an edge of the base layer (2).

14. The electronic circuit, according to claim 12, wherein:
a distance of the respective conductor tracks (3) from an edge of the base layer (2) is at least as great as the height of the conductor tracks (3).

15. The electronic circuit, according to claim 2, wherein:
the base layer (2) consists of an epoxy resin.
